(19) United States
(12) Patent Application Publication
(10) Pub. No.: US 2015/0034373 A1
(43) Pub. Date: Feb. 5, 2015

(54) WIRING STRUCTURE AND MANUFACTURING METHOD THEREOF

(71) Applicants: Yoshiki Nakashima, Tokyo (JP); Masahiro Kubo, Tokyo (JP); Akinobu Shibuya, Tokyo (JP)

(72) Inventors: Yoshiki Nakashima, Tokyo (JP); Masahiro Kubo, Tokyo (JP); Akinobu Shibuya, Tokyo (JP)

(73) Assignee: NEC Corporation, Minato-ku, Tokyo (JP)

(21) Appl. No.: 14/379,420

(22) PCT Filed: Feb. 13, 2013
(86) PCT No.: PCT/JP2013/000750

§ 371 Date: Aug. 18, 2014

(30) Foreign Application Priority Data
Feb. 16, 2012 (JP) 2012-031932

(51) Int. Cl. H05K 3/12; H05K 1/03; H05K 1/09

(52) U.S. Cl. CPC H05K 3/1275; H05K 1/09; H05K 1/0313; H05K 2201/0137; H05K 2201/0129
USPC 174/257; 29/846

(57) ABSTRACT

A wiring structure includes a substrate, a convexoconcave absorption layer including a convexoconcave portion on the substrate, a conductive layer pattern on at least a concave portion of the convexoconcave absorption layer, and an insulating layer pattern over the conductive layer pattern and the convexoconcave absorption layer, on at least the concave portion. This configuration provides a wiring structure and a manufacturing method thereof which enable to form fine multilayer wiring using microcontact printing or the like.

### TECHNICAL FIELD

The present invention relates to a wiring structure and a manufacturing method thereof which enable to form fine multilayer wiring using microcontact printing.

### BACKGROUND ART

In recent years, there is implemented manufacturing of a wiring configuration by a very simplified process, using application of printing technology. For instance, a wiring configuration described in Patent Literature 1 is such that a wiring pattern is transferred by applying functional ink on a plate having a convexoconcave pattern on a surface thereof, and pressing the convex portion of the plate against a substrate, as illustrated in FIG. 1. This process is generally called as microcontact printing.

In a wiring configuration by microcontact printing, in addition to forming of a single layer of conductive pattern as illustrated in FIG. 1 of Patent Literature 1, there is performed that a first layer of conductive pattern is applied with an insulating layer and another layer of conductive pattern is further formed thereon as illustrated in FIG. 6 of Patent Literature 1. In this configuration, an insulating layer is applied on the entire surface of a substrate by a spin-coat process or the like, and patterning thereof is not performed.

A multilayer wiring structure by microcontact printing is manufactured as follows. First of all, a first conductive pattern layer is formed on a substrate by microcontact printing. Subsequently, an insulating layer is applied over the entire surface of the substrate using a spin-coat method or the like. Then, a second conductive pattern layer is formed. In some cases, a semiconductor pattern layer may be formed thereafter to impart a transistor function, in addition to a wiring function.

On the other hand, a method for manufacturing a multilayer wiring structure is disclosed in Patent Literature 2. In Patent Literature 2, a flat wiring substrate is manufactured by performing a step of forming a metal conductive pattern on a surface of a carrier, a step of forming an insulating resin layer in a semi-cured state on the side of the carrier where the metal conductive pattern is formed, a step of curing the insulating resin layer, and a step of removing the carrier from the surfaces of the insulating resin layer and of the metal conductive pattern. By laminating such configured wiring substrates, a multilayer wiring structure is implemented.

Further, Patent Literature 3 discloses a multilayer wiring structure formed by pushing a conductive layer formed on a resin in a semi-cured state on a substrate into the semi-cured resin for flattening, and by crimping the substrate to a separately prepared substrate having a conductive layer.

### CITATION LIST

### Patent Literature

Patent literature 1: Japanese Laid-open Patent Publication No.

2010-147408

Patent literature 2: Japanese Laid-open Patent Publication No. 2002-076577

Patent literature 3: Japanese Laid-open Patent Publication No. 2008-060548

### SUMMARY OF INVENTION

### Technical Problem

However, the wiring structures disclosed in Patent Literature 1, Patent Literature 2, and Patent Literature 3 have the following problems. Specifically, Patent Literature 1 fails to provide a fine multilayer wiring structure. This is because transfer of a wiring pattern is disabled as wiring becomes finer, when forming wiring on a surface of a substrate having concaves and convexes by microcontact printing.

Although Patent Literature 2 and Patent Literature 3 implement a multilayer wiring structure, it is necessary to bond a plurality of substrates together. In bonding the substrates together, misalignment may occur between the substrates. As wiring becomes finer, the influence of misalignment increases, which may lower the manufacturing yield. Further, the process may be complicated due to the necessity of forming wiring structures on a plurality of substrates in advance, or the necessity of positioning, adhesion and the like derived from bonding the substrates to each other.

The following is the description about the problems to be solved in forming a fine multilayer wiring structure by microcontact printing.

The first problem is such that it is required to form an insulating layer of a certain thickness or more in order to secure sufficient insulation in transferring the insulating layer for forming a multilayer wiring structure. As a result, concaves and convexes may be formed on the surface of the insulating layer on which an upper conductive layer is to be transferred. When transferring a fine pattern on the surface having the concaves and convexes, it is not possible to form the fine pattern as intended, while following the concaves and convexes on the surface to be transferred. Specifically, in forming a fine pattern, it is necessary to select a plate material having a low modulus of elasticity in order to secure followability. Use of a plate material having a low modulus of elasticity may cause contact between convex patterns or transfer of ink applied on a portion other than a convex portion (a concave portion). Thereby, it is not possible to avoid transfer of an unintended pattern.

Reducing the aspect ratio of convex and concave patterns may avoid contact between convex patterns, even with use of a plate having a low modulus of elasticity. In this case, however, it becomes not possible to avoid transfer of ink applied in a concave portion. Contrary to the above, increasing the aspect ratio makes it less likely to allow ink applied in a concave portion to be transferred, while it becomes not possible to avoid contact between convex patterns. In this way, it is not possible to avoid these two issues by a plate having good followability with respect to concaves and convexes on the surface to be transferred, i.e., a plate having a low modulus of elasticity. It should be noted, however, it is possible to avoid transfer of ink applied in a concave portion, even with a low aspect ratio, as long as a fine pattern is not formed by a plate having a low modulus of elasticity, because the distance between concaves and convexes of a pattern can be sufficiently secured.

Further, in order to solve the above problem, there is proposed an idea of using a method for indirectly applying ink, in which ink is applied in advance on the surface of an ink supplier such as a flat wafer, instead of applying ink on the entirety of a stamp, and the ink is supplied only to a convex portion by causing a microcontact stamp to come in contact with the ink supplier. When forming a fine pattern, however, the ink on the ink supplier may infiltrate the concave portion of the stamp due to surface tension or the like. When letting the ink dry sufficiently in order to avoid the infiltration, ink supply itself may fail. Therefore, it is not possible to choose this method in forming a fine pattern.

There is also proposed an idea of separately providing a convex structure other than a circuit pattern in a concave portion of a convexoconcave pattern in order to avoid transfer of ink applied on a portion other than the convex portion, wherever possible. This method, however, may result in transferring an unwanted pattern in the aspect of circuit design. Thus, the method may limit the degree of freedom in design.

In Patent Literature 1, energy is applied in advance to a specific portion of a substrate of a transfer object by ashing or the like via a pattern mask. This method tries to avoid transfer of an unintended pattern by providing surface energy of different levels, and by allowing a portion where ink transfer is not intended to have low surface energy in advance. According to this method, however, it is not possible to avoid ink transfer over all the concave portions, when the distance between the convex portions is sufficiently large with respect to the height difference between concaves and convexes of a pattern.

The second problem is such that it is still not possible to follow a height difference of a sharp angle if the angle exceeds a predetermined value, even when the pattern to be transferred is not fine and the pattern can be transferred using a stamp having a low modulus of elasticity in order to secure followability. The pattern may be ruptured in the portion corresponding to the height difference, and it is not possible to form multilayer wiring.

The third problem is such that delamination between a substrate and each of the layers in contact with the substrate may occur during a process, when adhesion between the substrate of transfer object, and conductive ink or insulating ink to be transferred is low. This may lower the yield.

An object of the invention is to provide a wiring structure and a manufacturing method thereof which enable to implement a fine multilayer wiring structure by a simplified process using microcontact printing, while solving the problem such that it has not been possible to implement a fine multilayer wiring structure using microcontact printing, and solving the problem such that misalignment or complication of process has been occurred when implementing a fine multilayer wiring structure by bonding a plurality of substrates as described above.

### Solution to Problem

A wiring structure includes a substrate, a convexoconcave absorption layer including a convexoconcave portion on the substrate, a conductive layer pattern on at least a concave portion of the convexoconcave absorption layer, and an insulating layer pattern over the conductive layer pattern and the convexoconcave absorption layer, on at least the concave portion.

A method for manufacturing a wiring structure includes a step of forming a convexoconcave absorption layer on a substrate, a step of forming a conductive layer pattern on the convexoconcave absorption layer, a step of forming an insulating layer pattern on the convexoconcave absorption layer and on the conductive layer pattern, a step of pushing the insulating layer pattern and the conductive layer pattern into the convexoconcave absorption layer by pressurizing the insulating layer pattern, and a step of curing the convexoconcave absorption layer.

### Advantageous Effects of Invention

According to the invention, there are provided a wiring structure and a manufacturing method thereof, which make it easy to transfer a fine wiring pattern in forming a wiring pattern using microcontact printing, avoid rupture of a wiring pattern and suppress delamination between layers, whereby implementing a fine multilayer wiring structure by a simplified process using microcontact printing.

### BRIEF DESCRIPTION OF DRAWINGS

FIG. 1 is a diagram illustrating a sectional configuration of a wiring structure according to an embodiment of the invention;

FIG. 2 is a diagram illustrating a surface structure of the wiring structure according to the embodiment of the invention;

FIG. 3 is a diagram illustrating a sectional configuration of the wiring structure according to the embodiment of the invention;

FIG. 4A is a diagram illustrating a wiring configuration manufacturing method according to the embodiment of the invention;

FIG. 4B is a diagram illustrating the wiring structure manufacturing method according to the embodiment of the invention;

FIG. 4C is a diagram illustrating the wiring structure manufacturing method according to the embodiment of the invention;

FIG. 4D is a diagram illustrating the wiring structure manufacturing method according to the embodiment of the invention;

FIG. 4E is a diagram illustrating the wiring structure manufacturing method according to the embodiment of the invention;

FIG. 4F is a diagram illustrating the wiring structure manufacturing method according to the embodiment of the invention;

FIG. 5A is a diagram illustrating the wiring structure manufacturing method according to the embodiment of the invention;

FIG. 5B is a diagram illustrating the wiring structure manufacturing method according to the embodiment of the invention; and

FIG. 6 is a diagram illustrating characteristics of a thermosetting resin used in the embodiment of the invention.

### DESCRIPTION OF PREFERRED EMBODIMENT

In the following, the best mode of the invention is described in details referring to the drawings. The embodiment to be described in the following has technically preferred limitations in order to carry out the invention, however, the scope of the invention is not limited to the following.

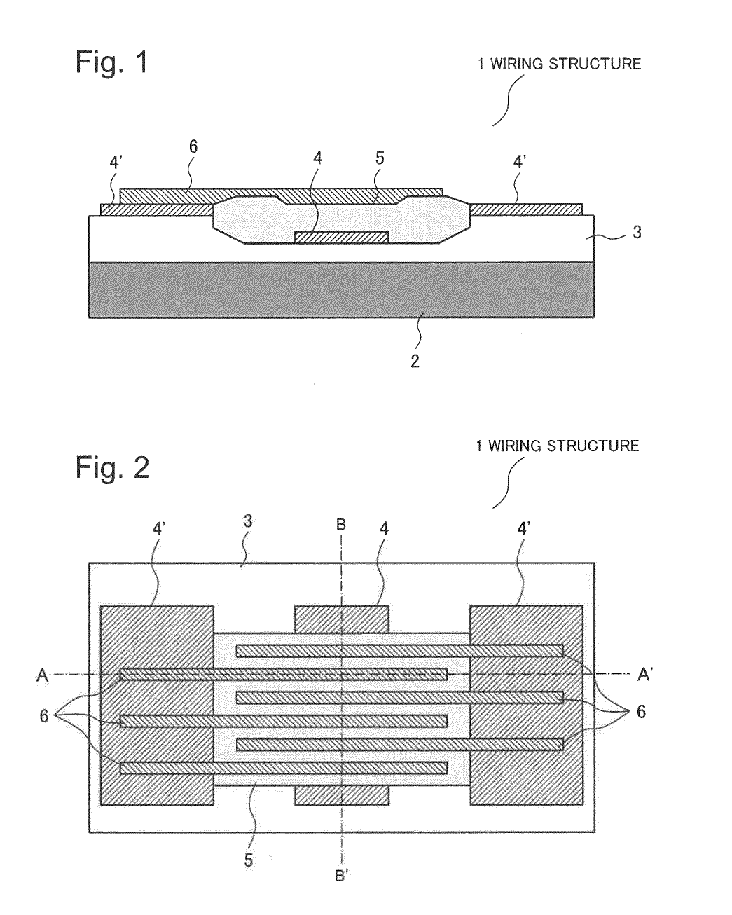

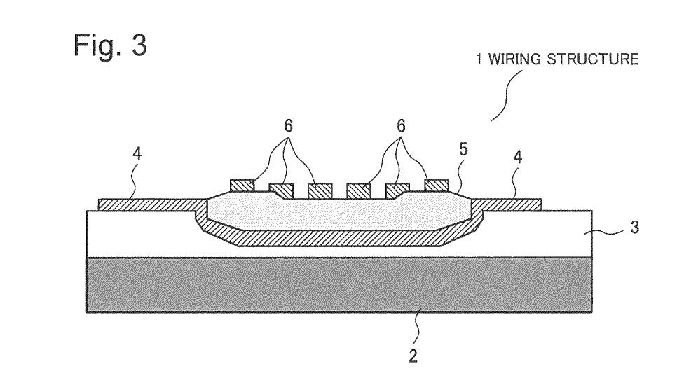

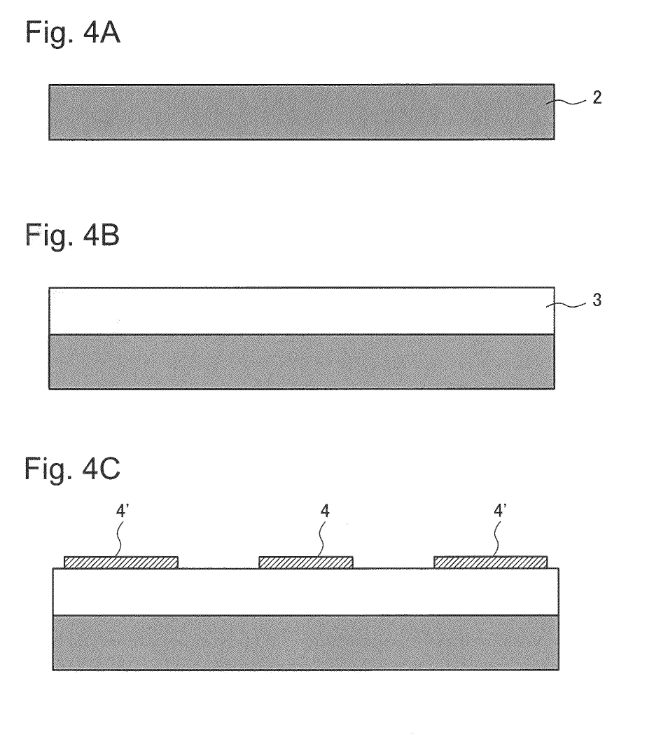

A wiring structure according to the embodiment of the invention is described referring to FIG. 1, FIG. 2, and FIG. 3. FIG. 1 illustrates a sectional view of the wiring structure according to the embodiment of the invention. FIG. 2 illustrates a plan view of the wiring structure according to the embodiment of the invention. FIG. 3 illustrates a sectional view of the wiring structure according to the embodiment of the invention. The cross section taken along the line A-A′ in FIG. 2 corresponds to FIG. 1. Further, the cross section taken along the line B-B′ in FIG. 2 corresponds to FIG. 3.

A wiring structure 1 illustrated in FIG. 1, FIG. 2, and FIG. 3 includes a substrate 2, and a convexoconcave absorption layer 3 on the substrate 2. A first conductive layer pattern 4 and a first conductive layer pattern 4′ are formed on the convexoconcave absorption layer 3. The first conductive layer pattern 4′ is formed concurrently with the first conductive layer pattern 4. A part of the first conductive layer pattern 4 is covered with an insulating layer pattern 5. The first conductive layer pattern 4 and the insulating layer pattern 5 are partially embedded in the convexoconcave absorption layer 3, and the bottom surface of the insulating layer pattern 5 is formed at a position closer to the substrate 2 than the surface of the convexoconcave absorption layer 3. As a result of this configuration, the height difference of the insulating layer pattern 5 with respect to the surface of the convexoconcave absorption layer 3 is reduced by the size corresponding to the embedded portion of the insulating layer pattern 5 into the convexoconcave absorption layer 3, whereby flatness is enhanced.

When forming a second conductive layer pattern 6 on the surface of the structure having the enhanced flatness as described above by transfer using microcontact printing, a special measure for following concaves and convexes is not required. Therefore, it is possible to use a plate material having a high modulus of elasticity. This makes it easy to form the fine second conductive layer pattern 6, without a possibility of contact between convex patterns and transfer of a concave portion.

Further, in the embodiment, it is possible to eliminate forming a large height difference. This is advantageous in preventing rupture of the second conductive layer pattern 6 due to a height difference.

Further, in the embodiment, the convexoconcave absorption layer 3 is in a semi-cured state during a manufacturing process. Therefore, the surface of the convexoconcave absorption layer 3 has a viscosity. This makes it possible to secure adhesion with respect to the conductive pattern 4 (and 4′) and the insulating layer pattern 5 to be formed on the convexoconcave absorption layer 3. In this state, each of the layers in contact with the convexoconcave absorption layer 3 is less likely to cause delamination from the convexoconcave absorption layer 3. This contributes to enhancement of the manufacturing yield.

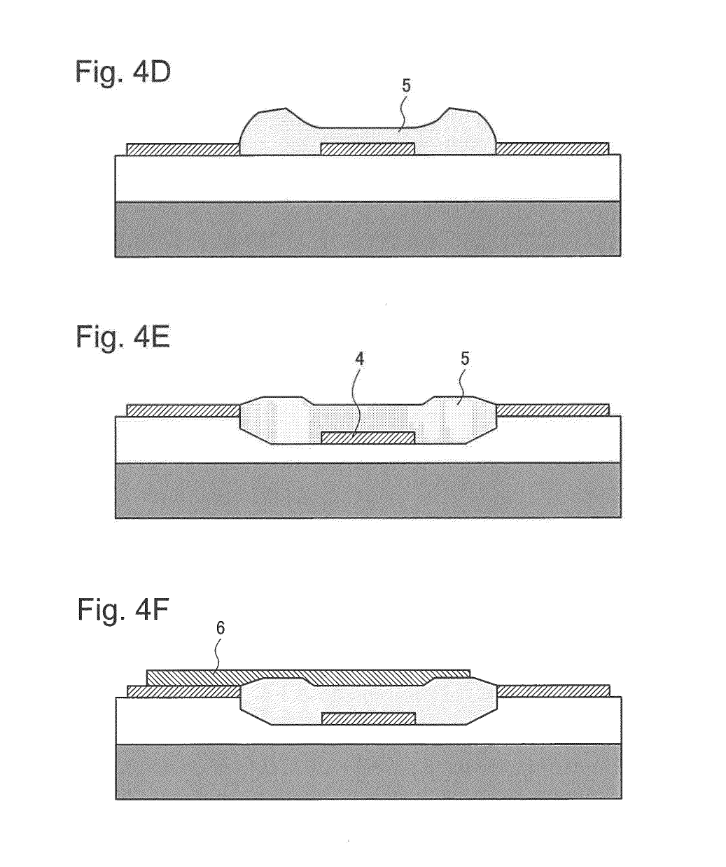

Next, a method for manufacturing the wiring structure according to the embodiment is described referring to FIGS. 4A to 4F. The materials and the processes to be applied are not limited to those in the embodiment, as far as advantageous effects substantially equivalent to those of the invention can be obtained.

As illustrated in FIG. 4A, first of all, the substrate 2 is prepared. The material of the substrate may be a flexible material such as a resin film, or a rigid material such as a printed circuit board. When a flexible substrate is selected, a wiring structure is also flexible. This is preferable since a flexible wiring structure is applicable to a wearable device, a flexible display, or the like.

Subsequently, as illustrated in FIG. 4B, the convexoconcave absorption layer 3 is formed on the substrate 2. A thermosetting resin is selected as a material of the convexoconcave absorption layer 3. When a liquefied material is selected, the convexoconcave absorption layer 3 is laminated by spin coat application, bar coat application, or the like. When a sheet-like material is selected, the convexoconcave absorption layer 3 is laminated by vacuum lamination or the like. Thereafter, the laminated convexoconcave absorption layer 3 is heated to be a semi-cured state (so-called B-stage). Alternatively, a sheet-like material prepared in advance in a semi-cured state may be laminated by vacuum lamination. As the convexoconcave absorption layer 3, there is selected a material having a thermosetting temperature higher than the sintering temperature or the thermosetting temperature of all the conductive layers and insulating layers to be laminated above the convexoconcave absorption layer 3. It is preferable that the convexoconcave absorption layer 3 is formed as thick as possible. However, the thickness of the convexoconcave absorption layer 3 is determined in view of the constraints relating to mounting in an electronic device or the like to which the wiring structure is embedded.

Further, the convexoconcave absorption layer 3 is required to be an insulator, because a conductive layer pattern is laminated in a subsequent process in the embodiment. However, the convexoconcave absorption layer 3 may be a conductor when an insulating layer is laminated in the subsequent process, followed by lamination of a conductive layer pattern, and when a part of the convexoconcave absorption layer 3 is connected to the conductive layer as a solid pattern to be used for grounding or the like in electric wiring. Further, the convexoconcave absorption layer 3 may be a conductor when another insulating layer as a solid pattern is laminated in the subsequent process in order to secure insulation.

In the subsequent process, as illustrated in FIG. 4C, the first conductive layer pattern 4 (and 4′) is formed. The first conductive layer pattern 4 (and 4′) is formed by transferring a pattern of conductive ink obtained by dissolving metal nanoparticles or the like such as silver, copper, gold, or aluminum in a solvent on the convexoconcave absorption layer 3 by microcontact printing or the like, followed by sintering. The temperature for sintering is required to be equal to or higher than the sintering temperature of the first conductive layer pattern but lower than the thermosetting temperature of the convexoconcave absorption layer 3. The surface of the convexoconcave absorption layer 3 is formed to be flat. Therefore, it is possible to form the first conductive layer 4 (and 4′) in a fine wiring pattern.

In the subsequent process, as illustrated in FIG. 4D, the insulating layer pattern 5′ is formed on the first conductive layer 4. A pattern of insulating ink obtained by dissolving a precursor of an insulating resin such as polyimide or epoxy in a solvent is transferred on the first conductive layer 4 and on a portion of the convexoconcave absorption layer 3 that is not covered with the first conductive layer 4′ using microcontact printing or the like, followed by curing. The temperature for curing is required to be equal to or higher than the thermosetting temperature of the insulating layer but lower than the thermosetting temperature of the convexoconcave absorption layer 3.

In the subsequent process, as illustrated in FIG. 4E, the first conductive layer pattern 4 and the insulating layer pattern 5 are pushed into the convexoconcave absorption layer 3 by applying pressure. Specifically, a film or the like subjected to mold releasing treatment is placed on the insulating layer pattern 5 to have a uniform pressure applied from above by a pressurization device or by a weight or the like. At the same time, the entirety is heated to a temperature equal to or higher than the temperature at which the convexoconcave absorption layer 3 is semi-cured, but lower than the thermosetting temperature of the convexoconcave absorption layer 3, to thereby impart fluidity to the convexoconcave absorption layer 3. Thus, the first conductive layer pattern 4 and the insulating layer pattern 5 are allowed to be pushed into the convexoconcave absorption layer 3. By performing the above process, the concaves and convexes of the insulating layer pattern 5 are reduced.

Further in the subsequent process (the state illustrated in FIG. 4E), the convexoconcave absorption layer 3 is cured by heating the convexoconcave absorption layer 3 to a temperature equal to or higher than the thermosetting temperature of the convexoconcave absorption layer 3. By performing the above process, a configuration absorbing the concaves and convexes of the insulating layer pattern 5 is held, and flatness of the surface is maintained.

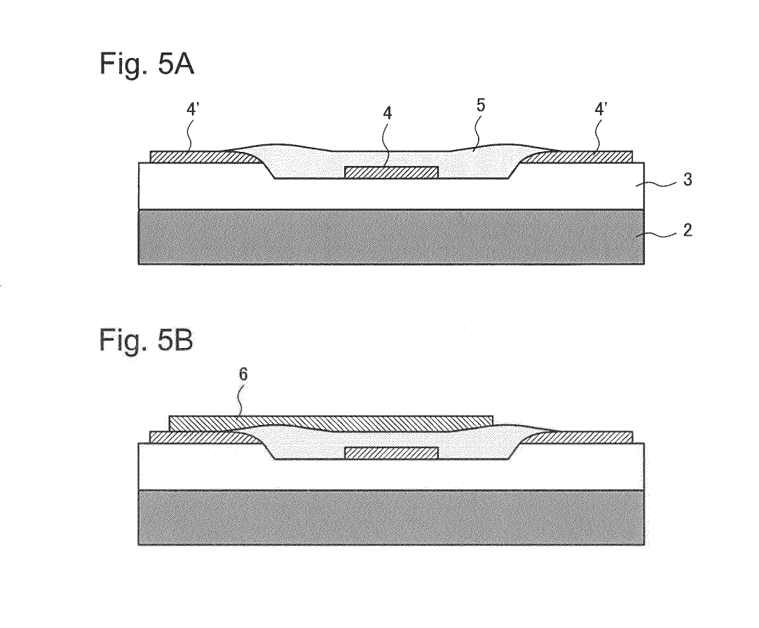

At the time of performing the above process, the configuration of the convexoconcave absorption layer 3 is as illustrated in FIG. 4E or in FIG. 5A depending on the modulus of elasticity of the convexoconcave absorption layer 3. When the modulus of elasticity of the convexoconcave absorption layer 3 is sufficiently low, as illustrated in FIG. 4E, the first conductive layer pattern 4 and the insulating layer pattern 5 are straightforwardly pushed into the convexoconcave absorption layer 3. On the other hand, when the modulus of elasticity of the convexoconcave absorption layer 3 is high to some extent, as illustrated in FIG. 5A, the insulating layer pattern 5 spreads out on the periphery. An object of the embodiment is to enable transfer of a fine wiring pattern in the process that follows the step illustrated in FIG. 4E or in FIG. 5A. Therefore, in both cases of FIG. 4E or FIG. 5A, concaves and convexes are reduced. Thus, the object of the invention is accomplished.

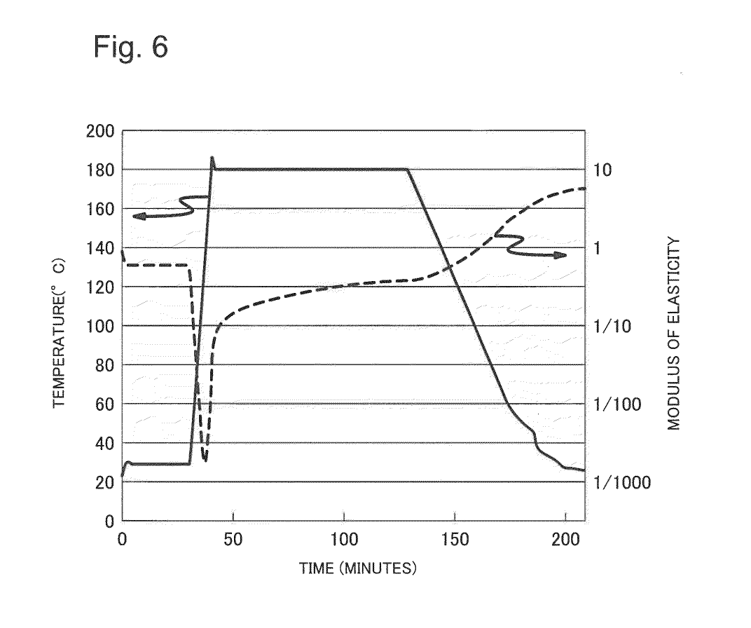

FIG. 6 illustrates a heat curing profile of a thermosetting epoxy resin used in the embodiment from a semi-cured state. As illustrated by the modulus of elasticity in FIG. 6 (assuming that the modulus of elasticity in a semi-cured state is 1), the thermosetting resin in a semi-cured state has a characteristic such that the modulus of elasticity is rapidly lowered before reaching the thermosetting temperature (180° C. in FIG. 6). Thereafter, when the resin is heated for a predetermined time (about 90 minutes in FIG. 6) at the thermosetting temperature, the modulus of elasticity is gradually increased. When the resin is cooled thereafter, finally, the modulus of elasticity is increased by about one digit, as compared with the modulus of elasticity before heating. In a process of pushing the first conductive layer pattern 4 and the insulating layer pattern 5 into the convexoconcave absorption pattern 3, it is possible to enhance flatness of the surface by retaining the temperature at a temperature lower than the thermosetting temperature of the convexoconcave absorption layer 3 (around 160° C., for example, in FIG. 6), and by pushing in a state where the modulus of elasticity of the convexoconcave absorption layer 3 is remarkably lowered.

In the subsequent process, as illustrated in FIG. 4F or in FIG. 5B, the second conductive pattern 6 is transferred. A pattern of conductive ink obtained by dissolving metal nanoparticles or the like such as silver, copper, gold, or aluminum in a solvent is transferred using microcontact printing or the like, followed by sintering. In this process, the temperature for sintering is equal to or higher than the sintering temperature of the second conductive layer pattern, and may be higher than the thermosetting temperature of the convexoconcave absorption layer 3.

The materials and processes to be applied in the present process are not limited to the above. Since a flat surface of transfer object is formed by the manufacturing method of the embodiment, it is possible to form the second conductive layer pattern 6 in a fine wiring pattern. Further, when it is obvious that the configuration as illustrated in FIG. 5A is obtained based on the relationship between the physical properties of the convexoconcave absorption layer 3 and the insulating layer pattern 5, a wiring pattern may be designed so that the first conductive layer pattern 4 and the second conductive layer pattern 6 are connected to each other, taking spread of the insulating layer pattern 5 into consideration.

In the embodiment, it is possible to configure the convexoconcave absorption layer 3 by a thermoplastic resin. Using the thermoplastic resin for the convexoconcave absorption layer 3 makes it possible to eliminate the constraints such that the sintering temperature or the thermosetting temperature of the first conductive layer pattern 4 (and 4′) or the insulating layer pattern 5 is required to be lower than the thermosetting temperature of the convexoconcave absorption layer 3. This provides a remarkable advantageous effect of increasing the degree of freedom in selecting a material.

As described above, according to the embodiment, reducing the convexes and concaves on a surface on which wiring is to be transferred makes it easy to transfer a fine wiring pattern, and makes it possible to suppress rupture of the wiring pattern resulting from convexes and concaves. Further, enhancing the interlayer adhesion makes it possible to suppress delamination between layers. Thus, the problem such that a fine multilayer wiring structure cannot be implemented by microcontact printing has been solved. Further, it is not necessary to form a multilayer wiring structure by bonding a plurality of substrates. Specifically, problems such as misalignment or complication of process involved in bonding the plurality of substrates are eliminated. Thus, it is possible to provide a wiring structure and a manufacturing method thereof which enable to form a fine multilayer wiring structure with a simplified process using microcontact printing.

### SUPPLEMENTAL NOTES

### Supplemental Note 1

A wiring structure, including:

a substrate;

a convexoconcave absorption layer including a convexoconcave portion on the substrate;

a conductive layer pattern on at least a concave portion of the convexoconcave absorption layer; and

an insulating layer pattern over the conductive layer pattern and the convexoconcave absorption layer, on at least the concave portion.

### Supplemental Note 2

The wiring structure according to Supplemental Note 1, wherein the convexoconcave absorption layer is a first thermosetting resin, the insulating layer pattern is a second thermosetting resin, and the conductive layer pattern is formed by metal particles.

### Supplemental Note 3

The wiring structure according to Supplemental Note 2, wherein a thermosetting temperature of the first thermosetting resin is higher than a thermosetting temperature of the second thermosetting resin and a sintering temperature of the metal particles.

### Supplemental Note 4

The wiring structure according to any one of Supplemental Notes 2 to 3, wherein the first thermosetting resin is an epoxy resin.

### Supplemental Note 5

The wiring structure according to any one of Supplemental Notes 2 to 4, wherein the second thermosetting resin is a polyimide resin or an epoxy resin.

### Supplemental Note 6

The wiring structure according to any one of Supplemental Notes 2 to 5, wherein the metal particles include silver, copper, gold, or aluminum.

### Supplemental Note 7

The wiring structure according to Supplemental Note 1, wherein the convexoconcave absorption layer is a thermoplastic resin.

### Supplemental Note 8

A method for manufacturing a wiring structure, including:

a step of forming a convexoconcave absorption layer on a substrate;

a step of forming a conductive layer pattern on the convexoconcave absorption layer;

a step of forming an insulating layer pattern on the convexoconcave absorption layer and on the conductive layer pattern;

a step of pushing the insulating layer pattern and the conductive layer pattern into the convexoconcave absorption layer by pressurizing the insulating layer pattern; and

a step of curing the convexoconcave absorption layer.

### Supplemental Note 9

The method for manufacturing a wiring structure according to Supplemental Note 8, wherein the convexoconcave absorption layer is a first thermosetting resin, the insulating layer pattern is a second thermosetting resin, and the conductive layer pattern is composed of metal particles,

wherein a thermosetting temperature of the first thermosetting resin is higher than a thermosetting temperature of the second thermosetting resin and a sintering temperature of the metal particles.

### Supplemental Note 10

The method for manufacturing a wiring structure according to Supplemental Note 9, wherein a temperature of the step of pushing is lower than the thermosetting temperature of the first thermosetting resin.

### Supplemental Note 11

The method for manufacturing a wiring structure according to any one of Supplemental Notes 9 to 10, wherein the step of forming the convexoconcave absorption layer includes a step of semi-curing the first thermosetting resin at a temperature lower than the thermosetting temperature of the first thermosetting resin.

### Supplemental Note 12

The method for manufacturing a wiring structure according to any one of Claims 9 to 11, wherein the step of forming the conductive layer pattern includes a step of sintering the metal particles at a temperature higher than the sintering temperature of the metal particles but lower than the thermosetting temperature of the first thermosetting resin.

### Supplemental Note 13

The method for manufacturing a wiring structure according to any one of Supplemental Notes 9 to 12, wherein the step of forming the insulating layer pattern includes a step of curing the second thermosetting resin at a temperature higher than the thermosetting temperature of the second thermosetting resin but lower than the thermosetting temperature of the first thermosetting resin.

### Supplemental Note 14

The method for manufacturing a wiring structure according to any one of Supplemental Notes 9 to 13, wherein the step of curing the convexoconcave absorption layer is performed at a temperature equal to or higher than the thermosetting temperature of the first thermosetting resin.

### Supplemental Note 15

A method for manufacturing a wiring structure, including: a step of forming a convexoconcave absorption layer on a substrate; a step of forming a conductive layer pattern on the convexoconcave absorption layer; a step of forming an insulating layer pattern on the convexoconcave absorption layer and on the conductive layer pattern; and a step of pushing the insulating layer pattern and the conductive layer pattern into the convexoconcave absorption layer by pressurizing the insulating layer pattern, wherein the convexoconcave absorption layer is a thermoplastic resin.

This application claims the priority based on Japanese Patent Application No. 2012-031932 filed on Feb. 16, 2012, and the entire disclosure of which is incorporated by reference herein.

### INDUSTRIAL APPLICABILITY

The invention relates to a wiring structure and a manufacturing method thereof which enable to form fine multilayer wiring using microcontact printing.

### REFERENCE SIGNS LIST

1 Wiring structure
2 Substrate
3 Convexoconcave absorption layer
4 First conductive layer pattern
5 Insulating layer pattern
6 Second conductive layer pattern

What is claimed is:

1. A wiring structure, comprising:
a substrate;
a convexoconcave absorption layer including a convexoconcave portion on the substrate;
a conductive layer pattern on at least a concave portion of the convexoconcave absorption layer; and
an insulating layer pattern over the conductive layer pattern and the convexoconcave absorption layer, on at least the concave portion.

2. The wiring structure according to claim 1, wherein the convexoconcave absorption layer is a first thermosetting resin, the insulating layer pattern is a second thermosetting resin, and the conductive layer pattern is formed by metal particles.

3. The wiring structure according to claim 2, wherein a thermosetting temperature of the first thermosetting resin is higher than a thermosetting temperature of the second thermosetting resin and a sintering temperature of the metal particles.

4. The wiring structure according to claim 2, wherein the first thermosetting resin is an epoxy resin.

5. The wiring structure according to claim 1, wherein the convexoconcave absorption layer is a thermoplastic resin.

6. A method for manufacturing a wiring structure, comprising:
forming a convexoconcave absorption layer on a substrate;
forming a conductive layer pattern on the convexoconcave absorption layer;
forming an insulating layer pattern on the convexoconcave absorption layer and on the conductive layer pattern;
pushing the insulating layer pattern and the conductive layer pattern into the convexoconcave absorption layer by pressurizing the insulating layer pattern; and
curing the convexoconcave absorption layer.

7. The method for manufacturing a wiring structure according to claim 6, wherein
the convexoconcave absorption layer is a first thermosetting resin, the insulating layer pattern is a second thermosetting resin, and the conductive layer pattern is formed by metal particles,
wherein a thermosetting temperature of the first thermosetting resin is higher than a thermosetting temperature of the second thermosetting resin and a sintering temperature of the metal particles.

8. The method for manufacturing a wiring structure according to claim 7, wherein a temperature in the step of pressing is lower than the thermosetting temperature of the first thermosetting resin.

9. The method for manufacturing a wiring structure according to claim 7, wherein the step of forming the convexoconcave absorption layer includes a step of semi-curing the first thermosetting resin at a temperature lower than the thermosetting temperature of the first thermosetting resin.

10. A method for manufacturing a wiring structure, comprising:
forming a convexoconcave absorption layer on a substrate;
forming a conductive layer pattern on the convexoconcave absorption layer; a step of forming an insulating layer pattern on the convexoconcave absorption layer and on the conductive layer pattern; and
pushing the insulating layer pattern and the conductive layer pattern into the convexoconcave absorption layer by pressurizing the insulating layer pattern, wherein the convexoconcave absorption layer is a thermoplastic resin.
